(19) United States
(12) Patent Application Publication
(10) Pub. No.: US 2018/0351476 A1
(43) Pub. Date: Dec. 6, 2018

(54) FLEXIBLE PRINTED CIRCUIT BOARD ACTUATOR

(71) Applicants: KOREA INSTITUTE OF SCIENCE AND TECHNOLOGY, Seoul (KR); CENTER OF HUMAN-CENTERED INTERACTION FOR COEXISTENCE, Seoul (KR)

(72) Inventors: Youngsu CHA, Seoul (KR); Junseok Lee, Seoul (KR); Jung Min Park, Seoul (KR); Bum-Jae You, Seoul (KR)

(73) Assignees: KOREA INSTITUTE OF SCIENCE AND TECHNOLOGY, Seoul (KR); CENTER OF HUMAN-CENTERED INTERACTION FOR COEXISTENCE, Seoul (KR)

(21) Appl. No.: 15/848,435

(22) Filed: Dec. 20, 2017

(30) Foreign Application Priority Data
Jun. 2, 2017 (KR) 10-2017-0069090

(51) Int. Cl. H02N 1/00; H05K 1/02

(52) U.S. Cl. CPC H02N 1/002; H05K 1/028

(57) ABSTRACT

Disclosed is a flexible printed circuit board (FPCB) actuator including an FPCB core having a first surface and a second surface, wherein the first surface and the second surface are parallel to each other, a first electrode installed on the first surface and having first parts, wherein the first parts are spaced apart from each other in a first direction at least in part, and a second electrode installed covering at least a portion of the second surface, wherein as control voltage is applied to the first and second electrodes, an electrostatic force generated between the first electrode and the second electrode in a second direction perpendicular to the first direction allows the FPCB core to make a bending motion.

### CROSS-REFERENCE TO RELATED APPLICATION

This application claims priority to Korean Patent Application No. 10-2017-0069090, filed on Jun. 2, 2017, and all the benefits accruing therefrom under 35 U.S.C. § 119, the contents of which in its entirety are herein incorporated by reference.

### BACKGROUND

### 1. Field

The present disclosure relates to a flexible printed circuit board actuator, and more particularly, to a flexible printed circuit board actuator that can make a bending motion by the electrostatic force generating between a plurality of electrodes.

[Description about National Research and Development Support]

This study was supported by the Global Frontier Support Project of Ministry of Science, ICT and Future Planning, Republic of Korea (Development of hand-based Seamless CoUI technology for collaboration among remote users, Project No. 1711052648) under the Korea Institute of Science and Technology.

### 2. Description of the Related Art

Recently, the trend of electronic products moves toward slim, light and compact design, the use of mobile electronic products including display is sharply increasing, and in keeping with this trend, flexible printed circuit board (FPCB) fabrication in the field of circuit board is on the increase.

FPCB has high heat resistance, bending resistance and chemical resistance and is very resistant to heat, so it is widely used as an essential component of all electronic products, for example, cameras, computers and peripheral devices, mobile phones, video and audio equipment, camcorders, printers, DVD, thin film transistor LCD (TFT LCD), satellite equipment, military equipment and medical equipment.

Particularly, FPCB is made of a material that is thin as much as about 0.1 mm and thus is easy to form fine patterns and has high bendability and flexibility, because of which FPCB is most actively used in mobile electronic devices, and as the usage is sharply increasing, mobile electronic devices including mobile phones are produced with various sizes and shapes to meet many consumers' tastes, and accordingly, FPCBs are also fabricated with various sizes and shapes.

Recently, much attention is paid to robots that can be applied to vibration generation and tactile feedback devices, and in which circuits and actuators are into one-body, and especially, there is a demand for development of a device for implementing an actuator using a flexible printed circuit board.

### SUMMARY

The present disclosure is designed to meet the demand, and therefore the present disclosure is directed to providing an actuator that can move by the electrostatic force generating between electrodes installed in one flexible printed circuit board (FPCB) structure.

To achieve the object, an FPCB actuator of the present disclosure includes an FPCB core having a first surface and a second surface, wherein the first surface and the second surface are parallel to each other, a first electrode installed on the first surface and having first parts, wherein the first parts are spaced apart from each other in a first direction at least in part, and a second electrode installed covering at least a portion of the second surface, wherein as control voltage is applied to the first and second electrodes, an electrostatic force generated between the first electrode and the second electrode in a second direction perpendicular to the first direction allows the FPCB core to make a bending motion.

The first electrode may further have a second part formed between the first parts spaced apart from each other to allow the first parts to be electrically connected.

The second part may be placed in the first direction to connect central areas between one end and the other end of the first parts.

The second part may connect each one of one ends of the first parts facing each other and the other ends of the first parts facing each other among the first parts.

Each of the first surface and the second surface may be two surfaces of the FPCB core facing opposite sides each other.

The second electrode may be installed covering the entire second surface. The first and second electrodes may have different polarities.

### BRIEF DESCRIPTION OF THE DRAWINGS

FIG. 1A is a perspective view of a flexible printed circuit board actuator of the present disclosure.

FIG. 1B is a top view of a flexible printed circuit board actuator of the present disclosure when viewed from the top.

FIG. 1C is a bottom view of a flexible printed circuit board actuator of the present disclosure when viewed from the bottom.

FIG. 2A is a cross-sectional view taken along the line of A-A′ in FIG. 1B.

FIG. 2B is a conceptual diagram showing the electrostatic force between first and second electrodes in FIG. 2A.

FIG. 3A is a conceptual diagram showing the operation of a flexible printed circuit board actuator formed as a cantilever.

FIG. 3B is a conceptual diagram showing the operation of a flexible printed circuit board actuator formed as a fixed beam.

FIG. 4 is a top view showing an example of a flexible printed circuit board actuator with a first electrode of a different shape.

### DETAILED DESCRIPTION

Hereinafter, the embodiments disclosed herein will be described in detail with reference to the accompanying drawings, in which identical or similar reference numerals are given to identical or similar elements, and an overlapping description is omitted herein. The suffix “unit” as used herein refers to elements or components, and it is only given or interchanged in consideration of facilitation of the description, and does not itself have any distinguishable meaning or role. Furthermore, in describing the embodiments disclosed herein, when a certain description of related well-known technology is deemed to render the essential subject matter of the embodiments disclosed herein ambiguous, its detailed description is omitted herein. It should be further understood that the accompanying drawings are only provided to facilitate the understanding of the embodiments disclosed herein, and the technical spirit disclosed herein is not limited by the accompanying drawings and covers all modifications, equivalents or substituents included in the spirit and technical scope of the present disclosure.

The terms including the ordinal number such as “first”, “second” and the like may be used to describe various elements, but the elements are not limited by the terms. The terms are only used to distinguish one element from another.

It will be understood that when an element is referred to as being “connected to” another element, it can be directly connected to the other element or intervening elements may be present.

As used herein, the singular forms are intended to include the plural forms as well, unless the context clearly indicates otherwise.

It will be further understood that the terms “comprises” or “includes” when used in this specification, specify the presence of stated features, integers, steps, operations, elements, components or groups thereof, but do not preclude the presence or addition of one or more other features, integers, steps, operations, elements, components, or groups thereof.

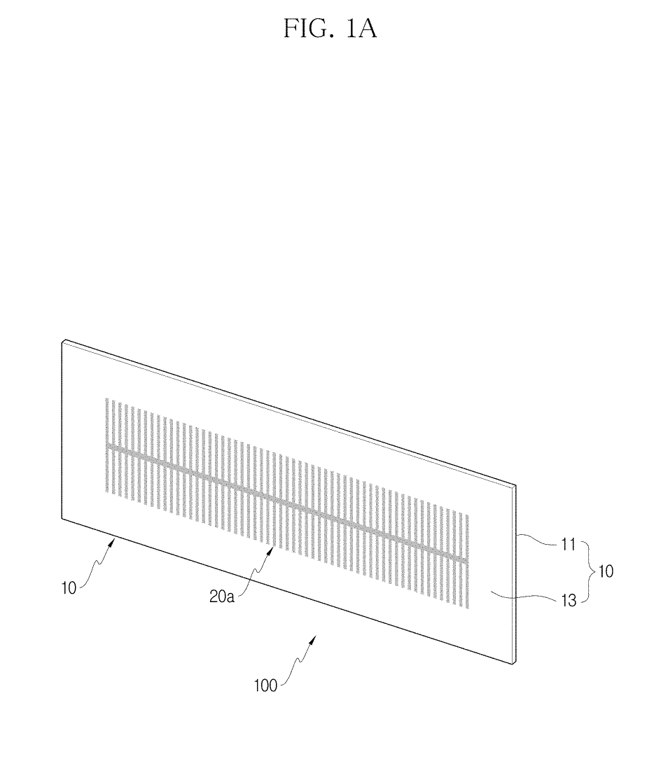

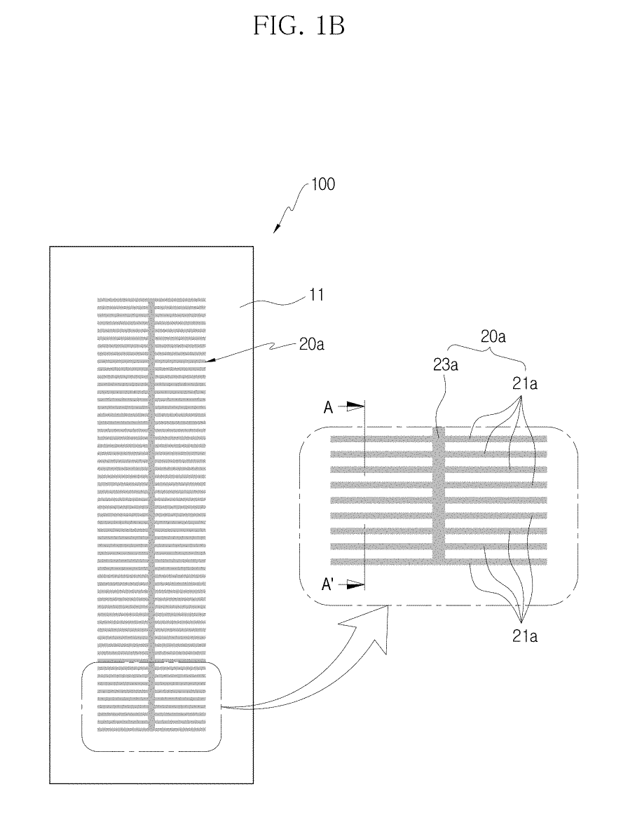

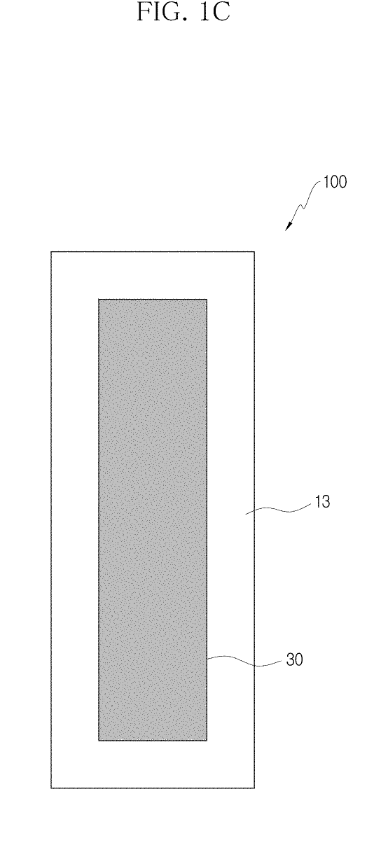

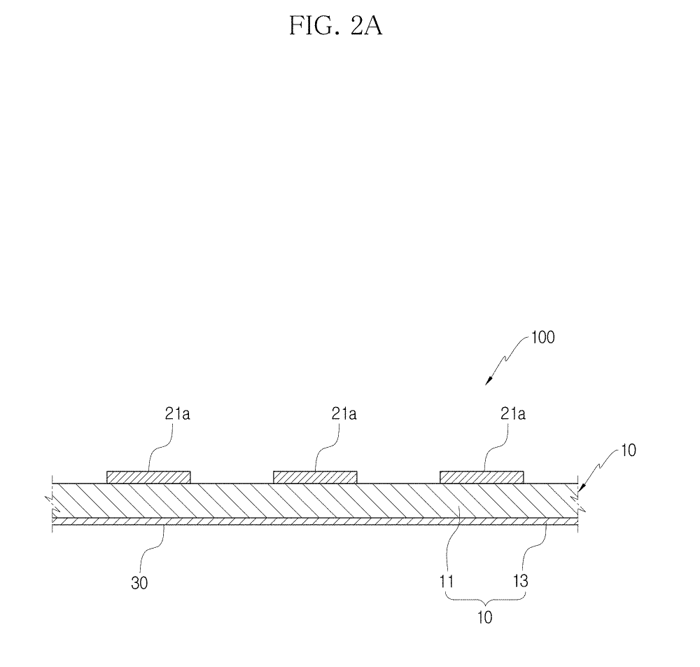

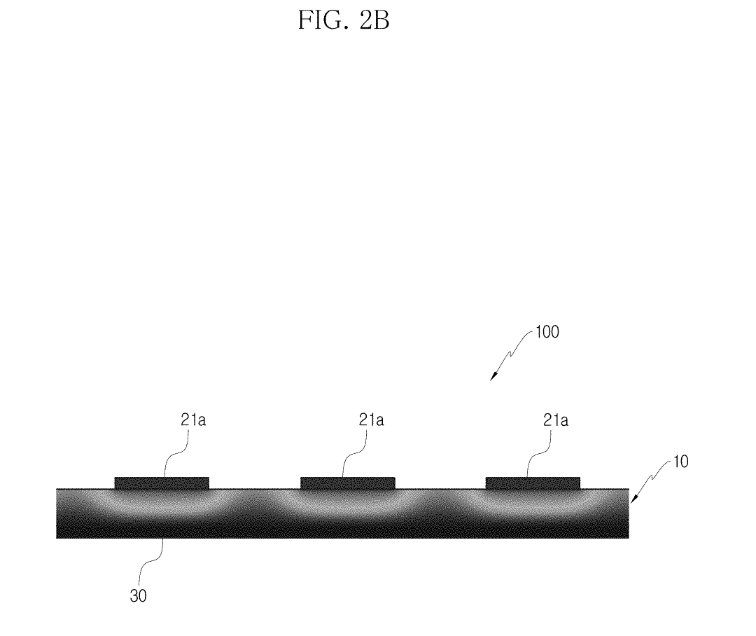

Referring to FIGS. 1A to 2A, a flexible printed circuit board (FPCB) actuator 100 of the present disclosure includes an FPCB core 10, and first and second electrodes 20a, 30.

The FPCB core 10 has first and second surfaces 11, 13. The first surface 11 and the second surface 13 are parallel to each other. For example, the first and second surfaces 11, 13 may be two parallel surfaces facing the opposite sides each other. Referring to FIGS. 1A to 1C, the first and second surfaces 11, 13 may be upper and lower surfaces of the FPCB core 10, and they face the opposite sides each other. In the present disclosure, the FPCB core 10 may be an FPCB core plate.

The first electrode 20a is installed on the first surface 11 of the FPCB core 10. Furthermore, the first electrode 20a has first parts 21a, and the first parts 21a are spaced apart from each other in a first direction at least in part. The first parts 21a may be made of a conductive material.

In the present disclosure, the first parts 21a of the first electrode 20a are spaced apart from each other in the first direction, and the first electrode 20a has each first part 21a placed in a direction perpendicular to the first direction. For example, each first part 21a may be placed in a direction orthogonal to the first direction. In the present disclosure, the first direction is a direction in which the first parts 21a are spaced apart from each other, and the first direction may be an up-down direction in FIG. 1B and a left-right direction in FIG. 2A.

The first electrode 20a may further have a second part 23a. The second part 23a may be connected to the first parts 21a to allow the first parts 21a to be connected. The second part 23a may be made of a conductive material. The second part 23a may be placed in a direction parallel to the first direction, and for example, each first part 21a may connect the central areas between one end and the other end of the first parts 21a. Referring to FIG. 1B, an example is shown in which the second part 23a is placed in the up-down direction to connect the central areas between one end and the other end of the first parts 21a, so that the first parts 21a are symmetric with respect to the second part 23a.

As described above, the first parts 21a of the first electrode 20a are spaced apart from each other in the first direction at least in part, and the second part 23a is connected to the first parts 21a to allow the first parts 21a to be connected, forming a comb structure.

Referring to FIGS. 1C and 2A, the second electrode 30 is installed on the second surface 13 of the FPCB core 10. Although FIG. 1C shows an example in which the second electrode 30 is installed on a portion of the second surface 13, dissimilar to this, the second electrode 30 may be installed covering the entire second surface 13.

That is, the first electrode 20a has the first parts 21a spaced apart from each other at least in part and the second part 23a is installed on the second surface 13, and thus the first and second electrodes 20a, 30 are placed with an asymmetric structure on the first and second surfaces 11, 13 of the FPCB core 10. Accordingly, an electrostatic force is produced between the first and second electrodes 20a, 30, allowing the FPCB core 10 to make a bending motion.

The first and second electrodes 20a, 30 may be opposite in polarity. For example, the first electrode 20a may be (+) polarity, and the second electrode 30 may be (−) polarity. Furthermore, each of the first and second electrodes 20a, 30 can be electrically connected to a power source, and as control voltage supplied from the power source is applied, an electrostatic force is generated between the first and second electrodes 20a, 30 in the second direction.

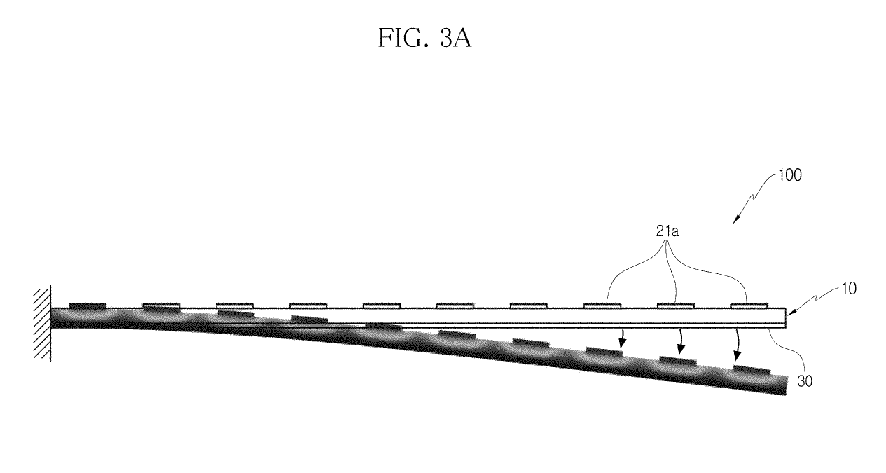

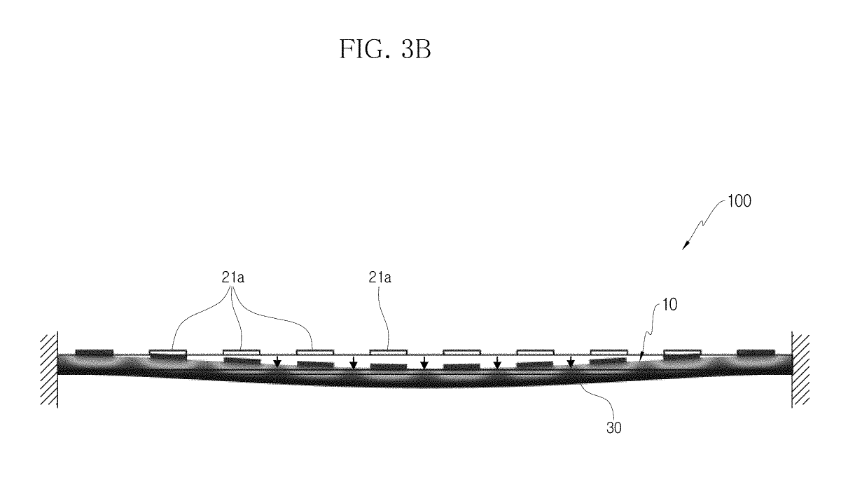

Accordingly, as the electrostatic force is generated in the second direction within one FPCB core 10, the FPCB core 10 is subjected to bending stress in the second direction and makes a bending motion. Meanwhile, in the present disclosure, the second direction is a direction perpendicular to the first direction. For example, the second direction may be an up-down direction in FIGS. 2A to 3B.

FIG. 2B shows an example of the electrostatic force generated between the first parts 21a of the first electrode 20a and the second electrode 30, and as shown in FIGS. 3A and 3B, the FPCB actuator 100 may make a bending motion.

FIG. 3A shows an example of the FPCB actuator 100 formed as a cantilever with one fixed end. In FIG. 3A, the FPCB core 10 is subjected to bending stress in downward direction by the electrostatic force generated between the first and second electrodes 20a, 30, and the maximum sag occurs at the right free end of the FPCB core

Furthermore, FIG. 3B shows an example of the FPCB actuator 100 formed as a fixed beam with two fixed ends, and the FPCB core 10 is subjected to bending stress in downward direction by the electrostatic force generated between the first and second electrodes 20a, 30, and the maximum sag occurs at the central area between the two ends.

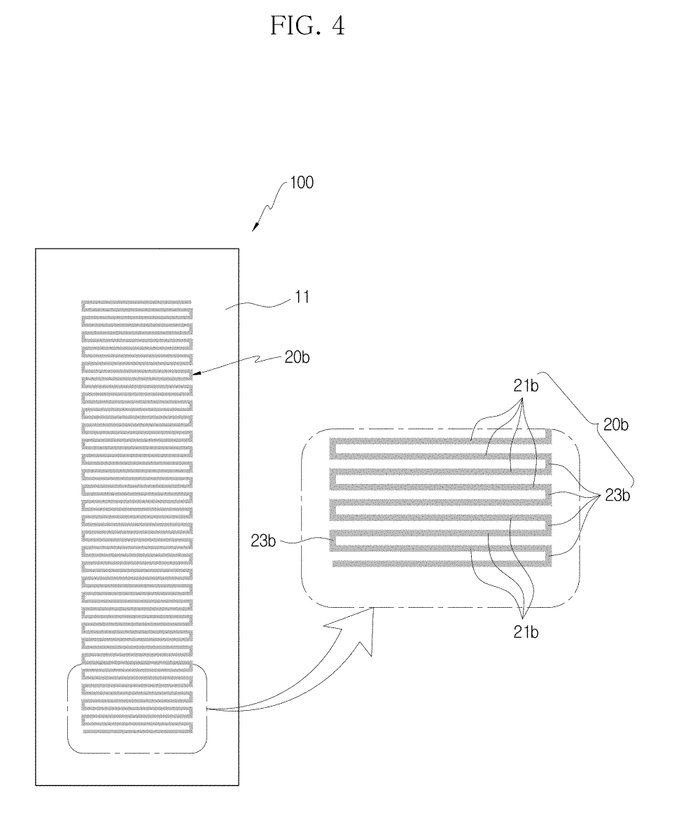

Referring to FIG. 4, shown is an example of the first electrode 20b in a different shape from the first electrode 20a shown in FIG. 1A.

The second part 23b of the first electrode 20b connects each one of one ends of the first parts 21b facing each other and the other ends of the first parts 21b facing each other among the first parts 21b. In FIG. 4, one ends of adjacent first parts on the left side are connected by the second part, and the other ends of adjacent first parts on the right side are connected by the second part, and this shape continues to form the first electrode 20b such that L shapes are connected multiple times.

The first electrode 20b shown in FIG. 4 has a structure in which at least portions are spaced apart from each other in the first direction similar to the first electrode 20a shown in FIG. 1A, and the second part 23b is connected to the first parts 21b to allow the first parts 21b to be connected.

The FPCB actuator 100 of another embodiment of the present disclosure has the same configuration as the FPCB actuator 100 described in FIGS. 1A and 1B, except that the first electrode 20b is formed in a different shape, and thus its detailed description is omitted herein.

The FPCB actuator 100 of the present disclosure can be applied to vibration generation and tactile feedback devices. Furthermore, the FPCB actuator 100 of the present disclosure can realize robots in which circuits and actuators are incorporated into one-body.

With the first parts spaced apart from each other in part, the FPCB actuator of the present disclosure can move due to bending stress produced by the electrostatic force between the first electrode and the second electrode.

Furthermore, the FPCB actuator of the present disclosure forms a dynamic structure by generating the electrostatic force between the first and second electrodes with an asymmetric structure.

Additionally, the FPCB actuator of the present disclosure has an advantage in the fabrication process, because actuation is accomplished by adding the electrode form onto the existing FPCB without the use of an additional material.

Meanwhile, the use of FPCB as an actuator accomplishes the integrated form of circuits and actuators, and through this, realizes vibration and tactile devices, and especially, achieves miniaturization and lightweight in the field of soft robotics development.

The FPCB actuator 100 as described above is not limited to the configuration and method of the embodiments described above, and some or all of the embodiments may be selectively combined to make various modifications.

It is obvious to those skilled in the art that the present disclosure may be embodied in another specific form without departing from the spirit and essential feature of the present disclosure. Therefore, it should be noted that the detailed description is for illustration only, but not intended to limiting in all aspects. The scope of the present disclosure should be determined by the reasonable interpretation of the appended claims, and all modifications within the equivalent scope of the present disclosure falls in the scope of the present disclosure.

### DETAILED DESCRIPTION OF MAIN ELEMENTS

100: Flexible printed circuit board actuator
10: FPCB core 11: First surface 13: Second surface
20a, 20b: First electrode 21a, 21b: First part 23a, 23b: Second part
30: Second electrode

What is claimed is:

1. A flexible printed circuit board (FPCB) actuator, comprising:
an FPCB core having a first surface and a second surface, wherein the first surface and the second surface are parallel to each other and spaced apart;
a first electrode installed on the first surface and having first parts, wherein the first parts are spaced apart from each other in a first direction at least in part; and
a second electrode installed covering at least a portion of the second surface,
wherein as control voltage is applied to the first and second electrodes, an electrostatic force generated between the first electrode and the second electrode in a second direction perpendicular to the first direction allows the FPCB core to make a bending motion.

2. The flexible printed circuit board actuator according to claim 1, wherein the first electrode further has a second part formed between the first parts spaced apart from each other to allow the first parts to be electrically connected.

3. The flexible printed circuit board actuator according to claim 2, wherein the second part is placed in the first direction to connect central areas between one end and the other end of the first parts.

4. The flexible printed circuit board actuator according to claim 2, wherein the second part connects each one of one ends of the first parts facing each other and the other ends of the first parts facing each other among the first parts.

5. The flexible printed circuit board actuator according to claim 1, wherein each of the first surface and the second surface is two surfaces of the FPCB core facing opposite sides each other.

6. The flexible printed circuit board actuator according to claim 1, wherein the second electrode is installed covering the entire second surface.

7. The flexible printed circuit board actuator according to claim 1, wherein the first and second electrodes have different polarities.
